(19) United States
(12) Patent Application Publication
(10) Pub. No.: US 2023/0269980 A1
(43) Pub. Date: Aug. 24, 2023

(54) DISPLAY APPARATUS

(71) Applicant: Samsung Display Co., Ltd., Yongin-si (KR)

(72) Inventors: Kangmoon Jo, Yongin-si (KR); Unbyoll Ko, Yongin-si (KR); Sowoon Kim, Yongin-si (KR); Seongyoung Lee, Yongin-si (KR)

(21) Appl. No.: 18/114,106

(22) Filed: Feb. 24, 2023

(30) Foreign Application Priority Data
Feb. 24, 2022 (KR) 10-2022-0024572

(51) Int. Cl. H10K 59/131

(52) U.S. Cl. CPC H10K 59/131

(57) ABSTRACT

Provided is a display apparatus capable of stably applying an electrical signal to a gate electrode. The display apparatus includes substrate, an oxide semiconductor layer above the substrate, and including a first channel area, and a second channel area spaced from the first channel area, a first conductive layer between the substrate and the oxide semiconductor layer, and including a first gate electrode overlapping the first channel area, and a second conductive layer above the oxide semiconductor layer, and including a shielding layer overlapping the first channel area, and a second gate electrode overlapping the second channel area.

### CROSS-REFERENCE TO RELATED APPLICATION

This application claims priority, to and the benefit of, Korean Patent Application No. 10-2022-0024572, filed on Feb. 24, 2022 in the Korean Intellectual Property Office, the disclosure of which is incorporated herein in its entirety by reference.

### BACKGROUND

### 1. Field

One or more embodiments relate to a display apparatus capable of stably applying an electrical signal to a gate electrode.

### 2. Description of the Related Art

Display apparatuses visually display data. Display apparatuses are used as displays of small products, such as mobile phones, or as displays of large products, such as televisions.

A display apparatus includes a display element and a pixel circuit including a transistor and a storage capacitor, and the display element is driven by the pixel circuit.

### SUMMARY

A conventional display apparatus may have a problem in that a voltage that is different from a preset voltage is applied to a gate electrode due to a parasitic capacitance, or in that the voltage that is applied to the gate electrode may not be constantly maintained due to a parasitic capacitance.

One or more embodiments include a display apparatus capable of stably applying an electrical signal to a gate electrode. However, aspects of embodiments according to the disclosure are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a display apparatus includes a substrate, an oxide semiconductor layer above the substrate, and including a first channel area, and a second channel area spaced from the first channel area, a first conductive layer between the substrate and the oxide semiconductor layer, and including a first gate electrode overlapping the first channel area, and a second conductive layer above the oxide semiconductor layer, and including a shielding layer overlapping the first channel area, and a second gate electrode overlapping the second channel area.

The shielding layer and the second gate electrode may include a same material and may have a same layer structure.

The display apparatus may further include a first insulating layer covering the first conductive layer, and between the first conductive layer and the oxide semiconductor layer, and a second insulating layer covering the oxide semiconductor layer, and between the oxide semiconductor layer and the second conductive layer, wherein the oxide semiconductor layer further includes a first connection area contacting the first channel area, and at least partially having different electrical properties from electrical properties of the first channel area, and a second connection area contacting the second channel area, and at least partially having different electrical properties from electrical properties of the second channel area, and wherein the second conductive layer further includes a first connection electrode electrically connected to the first connection area via a first contact hole defined by the second insulating layer, and a second connection electrode spaced from the first connection electrode, and electrically connected to the second connection area via a second contact hole defined by the first insulating layer and the second insulating layer.

The first insulating layer may cover the first conductive layer to correspond to an entire surface of the substrate, wherein the second insulating layer is between the first insulating layer and the second conductive layer outside the oxide semiconductor layer.

The second insulating layer may be below the second conductive layer.

The first connection electrode may be integrally formed with the shielding layer.

The first conductive layer may further include a scan line extending in a first direction.

The second conductive layer may further include a data line extending in a second direction crossing the first direction.

The first conductive layer may further include a connection line for electrically connecting the data line and the second connection electrode.

The first conductive layer may include a first capacitor electrode, wherein the oxide semiconductor layer includes a second capacitor electrode overlapping the first capacitor electrode, and wherein the second capacitor electrode has different electrical properties from electrical properties of the first channel area.

The display apparatus may further include a display element electrically connected to the second capacitor electrode, and including a pixel electrode, an emission layer, and an opposite electrode.

The second capacitor electrode may be directly in contact with the pixel electrode.

According to one or more embodiments, a display apparatus includes a substrate, an oxide semiconductor layer above the substrate, and including a first channel area, and a second channel area spaced from the first channel area, a first conductive layer between the substrate and the oxide semiconductor layer, and including a first gate electrode overlapping the first channel area, and a second gate electrode overlapping the second channel area, and a second conductive layer above the oxide semiconductor layer, and including a shielding layer overlapping the first channel area.

The first gate electrode and the second gate electrode may include a same material and have a same layer structure.

The display apparatus may further include a first insulating layer covering the first conductive layer, and between the first conductive layer and the oxide semiconductor layer, and a second insulating layer covering the oxide semiconductor layer, and between the oxide semiconductor layer and the second conductive layer, wherein the oxide semiconductor layer further includes a first connection area contacting the first channel area, and a second connection area contacting the second channel area, and wherein the second conductive layer further includes a first connection electrode electrically connected to the first connection area via a first contact hole defined by the second insulating layer, and a second connection electrode spaced from the first connection electrode, and electrically connected to the second connection area via a second contact hole defined by the second insulating layer.

The first connection electrode may be integrally formed with the shielding layer.

The second conductive layer may further include a scan line extending in a first direction.

The first conductive layer may further include a data line extending in a second direction crossing the first direction.

The second conductive layer may further include a connection line integrally formed with the second connection electrode, and electrically connected to the data line.

The display apparatus may further include a first connection metal layer above the first connection area, and corresponding to the first connection area, and a second connection metal layer above the second connection area, and corresponding to the second connection area.

The first conductive layer may include a first capacitor electrode, wherein the oxide semiconductor layer includes a second capacitor electrode overlapping the first capacitor electrode, and wherein the display apparatus further includes a capacitor metal layer above the second capacitor electrode, and corresponding to the second capacitor electrode.

The display apparatus may further include a display element electrically connected to the second capacitor electrode, and including a pixel electrode, an emission layer, and an opposite electrode.

The capacitor metal layer may be directly in contact with the pixel electrode.

These and/or other aspects will become apparent and more readily appreciated from the following description of the embodiments, the claims, and the accompanying drawings.

### BRIEF DESCRIPTION OF THE DRAWINGS

The above and other aspects of embodiments of the disclosure will be more apparent from the following description taken in conjunction with the accompanying drawings, in which:

FIG. 1 is a schematic plan view of a portion of a display apparatus according to one or more embodiments;

FIG. 2 is a schematic cross-sectional view of a portion of a display apparatus according to one or more embodiments;

FIG. 3 is an equivalent circuit diagram illustrating a display element included in a light-emitting panel and a pixel circuit connected to the display element, according to one or more embodiments;

FIG. 4 is a schematic layout diagram illustrating respective locations of transistors and a capacitor in pixels included in a display apparatus according to one or more embodiments;

FIGS. 5 through 8 are schematic layout diagrams illustrating respective components of the transistors and the capacitor for each layer of the display apparatus of FIG. 4;

FIG. 9A is a schematic cross-sectional view taken along the line I-I′ of the display apparatus of FIG. 4;

FIGS. 9B through 9D are schematic cross-sectional views taken along the line I-I′ of the display apparatus of FIG. 4, and illustrating a process of manufacturing a portion of the display apparatus of FIG. 4;

FIG. 10 is a schematic cross-sectional view taken along the line II-II′ of the display apparatus of FIG. 4;

FIGS. 11 through 14 are schematic cross-sectional views taken along the line II-II′ of the display apparatus of FIG. 4, and illustrating a process of manufacturing a portion of the display apparatus of FIG. 4;

FIG. 15 is a schematic layout diagram illustrating respective locations of transistors and a capacitor in pixels included in a display apparatus according to one or more other embodiments;

FIGS. 16 through 19 are schematic layout diagrams illustrating respective components of the transistors and the capacitor for each layer of the display apparatus of FIG. 15;

FIG. 20 is a schematic cross-sectional view taken along the line III-III′ of the display apparatus of FIG. 15;

FIG. 21 is a schematic cross-sectional view taken along the line IV-IV′ of the display apparatus of FIG. 15; and

FIGS. 22 through 24 are schematic cross-sectional views taken along the line IV-IV′ of the display apparatus of FIG. 15, and illustrating a process of manufacturing a portion of the display apparatus of FIG. 15.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” may include A, B, or A and B. As used herein, “or” generally means “and/or,” and the term “and/or” includes any and all combinations of one or more of the associated listed items. For example, the expression, such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

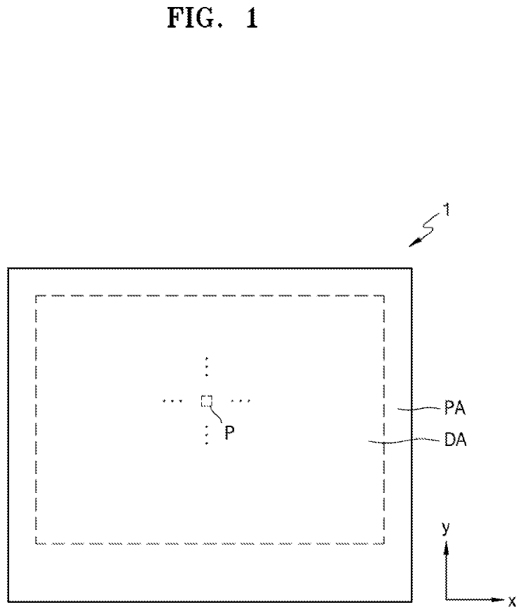

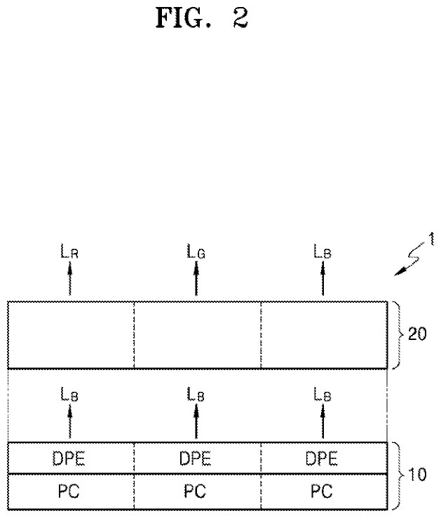

FIG. 1 is a schematic plan view of a portion of a display apparatus 1 according to one or more embodiments, and FIG. 2 is a schematic cross-sectional view of a portion of the display apparatus 1 according to one or more embodiments.

As shown in FIG. 1, the display apparatus 1 may include a display area DA in which a plurality of pixels P are arranged, and a peripheral area PA located outside the display area DA. The peripheral area PA may entirely surround the display area DA.

The display area DA may have the shape of a polygon including a quadrangle, as shown in FIG. 1. For example, the display area DA may have a rectangular shape in which a horizontal length is greater than a vertical length, a rectangular shape in which a horizontal length is less than a vertical length, or a square shape. Alternatively, the display area DA may have any of various shapes, such as an oval or a circle.

As shown in FIG. 2, the display apparatus 1 may include a light-emitting panel 10 and a filter panel 20 stacked on each other. The light-emitting panel 10 may include a plurality of display elements DPE, and each of the display elements DPE is electrically connected to a circuit PC (hereinafter, referred to as a pixel circuit PC). The display elements DPE and the pixel circuits PC may be arranged in the display area DA.

The display area DA may provide an image (e.g., predetermined image) by using light of the display elements DPE. For example, blue light LB emitted by the display elements DPE may be converted into red light LR and green light LG while passing through the filter panel 20, or may pass through the filter panel 20 without being converted. The display apparatus 1 may provide an image (e.g., predetermined image) by using light that is converted by the filter panel 20 or that is transmitted by the filter panel 20 without being converted, for example, the red light LR, the green light LG, and the blue light LB.

The peripheral area PA is a non-display area that provides no images, and may surround the entirety of the display area DA. A driver or a main power line for providing an electrical signal or power to the pixel circuits PC may be arranged in the peripheral area PA. The peripheral area PA may include a pad that is an area capable of being electrically connected to an electronic device or a printed circuit board (PCB).

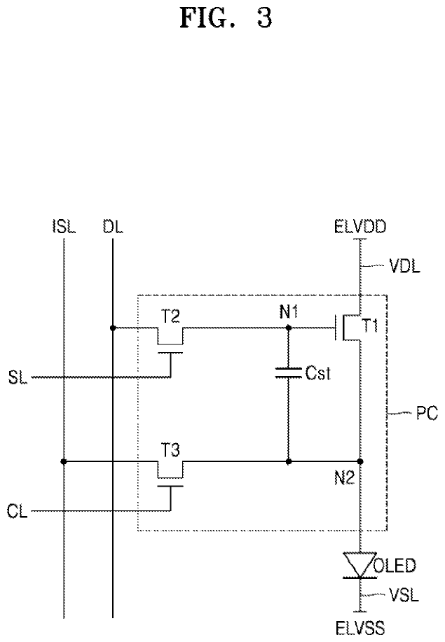

FIG. 3 is an equivalent circuit diagram illustrating a display element DPE included in a light-emitting panel and a pixel circuit PC connected to the display element DPE, according to one or more embodiments. As shown in FIG. 3, the display element DPE, for example, an organic light-emitting diode OLED, may be electrically connected to the pixel circuit PC. In detail, a pixel electrode of the organic light-emitting diode OLED may be electrically connected to the pixel circuit PC, and an opposite electrode of the organic light-emitting diode OLED may be electrically connected to a common voltage line VSL providing a common power supply voltage ELVSS. The organic light-emitting diode OLED may emit light with a brightness corresponding to a current amount provided by the pixel circuit PC.

The pixel circuit PC may include a first transistor T1, a second transistor T2, a third transistor T3, and a storage capacitor Cst. Each of the first transistor T1, the second transistor T2, and the third transistor T3 may be an oxide semiconductor thin-film transistor including a semiconductor layer formed of an oxide semiconductor, or may be a silicon semiconductor thin-film transistor including a semiconductor layer formed of polysilicon.

The first transistor T1 may be a driving transistor. One connection electrode of the first transistor T1 may be electrically connected to the pixel electrode of the organic light-emitting diode OLED, and the other connection electrode of the first transistor T1 may be electrically connected to a driving voltage line VDL that supplies a driving power supply voltage ELVDD. A first gate electrode of the first transistor T1 may be electrically connected to a first node N1. The first transistor T1 may control a current amount flowing through the organic light-emitting diode OLED from the driving power supply voltage ELVDD in accordance with a voltage of the first node N1.

The second transistor T2 may be a switching transistor. One connection electrode of the second transistor T2 may be electrically connected to a data line DL, and the other connection electrode of the second transistor T2 may be electrically connected to the first node N1. A second gate electrode of the second transistor T2 may be electrically connected to a scan line SL. The second transistor T2 may be turned on when a scan signal is supplied to the scan line SL, and may electrically connect the data line DL to the first node N1.

The third transistor T3 may be an initialization transistor and/or a sensing transistor. One connection electrode of the third transistor T3 may be electrically connected to an initialization-sensing line ISL, and the other connection electrode of the third transistor T3 may be electrically connected to a second node N2. A third gate electrode of the third transistor T3 may be electrically connected to a control line CL.

The third transistor T3 may be turned on when a control signal is supplied to the control line CL, and may electrically connect the initialization-sensing line ISL to the second node N2. According to some embodiments, the third transistor T3 may be turned on according to a signal received through the control line CL to initialize the pixel electrode of the organic light-emitting diode OLED by using an initializing voltage from the initialization-sensing line ISL. According to some embodiments, the third transistor T3 may be turned on when the control signal is supplied to the control line CL, and may sense property information, or characteristic information, of the organic light-emitting diode OLED. The third transistor T3 may function both as the above-described initialization transistor, and as the above-described sensing transistor, or may include one of the two functions. According to some embodiments, when the third transistor T3 includes the function as the initialization transistor, the initialization-sensing line ISL may be referred to as an initializing voltage line, and, when the third transistor T3 includes the function as the sensing transistor, the initialization-sensing line ISL may be referred to as a sensing line. An initialization operation and a sensing operation of the third transistor T3 may be individually conducted or may be concurrently or substantially simultaneously conducted. In other words, the third transistor T3 may be an initialization transistor and/or a sensing transistor. For convenience of description, a case where the third transistor T3 has both the function of the initialization transistor and the function of the sensing transistor will be described in detail.

The storage capacitor Cst may be connected between the first node N1 and the second node N2. For example, one capacitor electrode of the storage capacitor Cst may be electrically connected to the first gate electrode of the first transistor T1, and the other capacitor electrode of the storage capacitor Cst may be electrically connected to the pixel electrode of the organic light-emitting diode OLED.

In FIG. 3, the pixel circuit PC includes three transistors and one storage capacitor. However, according to one or more other embodiments, the number of transistors or the number of storage capacitors may vary according to a design of the pixel circuit PC.

Although the display element DPE includes the organic light-emitting diode OLED including an organic material in FIG. 3, embodiments are not limited thereto. According to one or more other embodiments, the display element DPE may be an inorganic light-emitting diode including an inorganic material. The inorganic light-emitting diode may include a PN diode including materials based on an inorganic material semiconductor. When a voltage is applied to the PN junction diode in a forward direction, holes and electrons are injected, and energy generated by recombination of the holes and the electrons is converted into light energy to thereby emit light of a color (e.g., predetermined color). The aforementioned inorganic light-emitting diode may have a width of several to several hundreds of micrometers. According to some embodiments, the aforementioned inorganic light-emitting diode may be referred to as a micro LED.

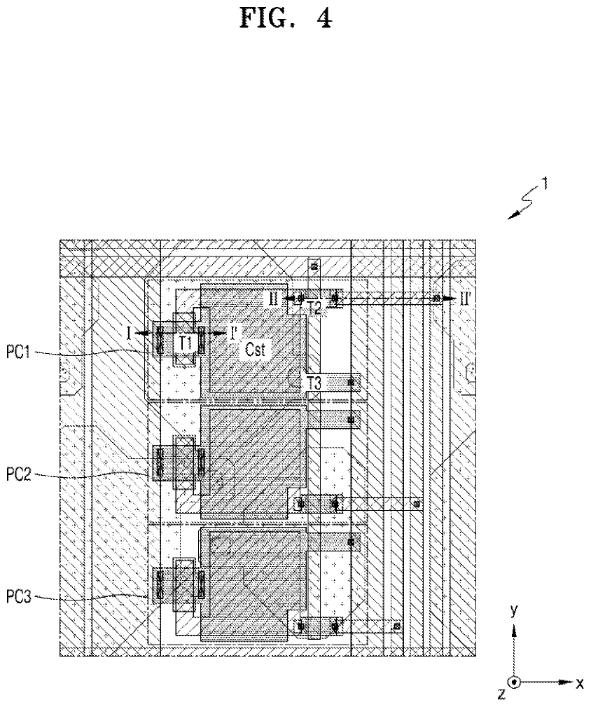

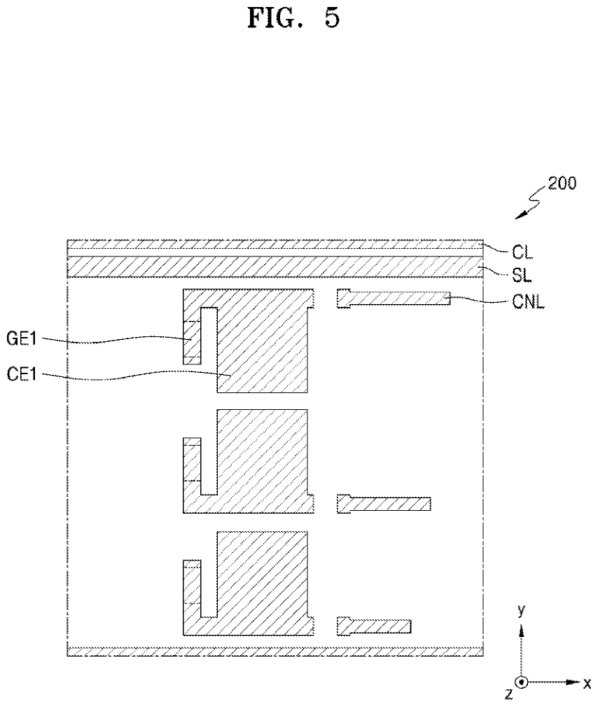

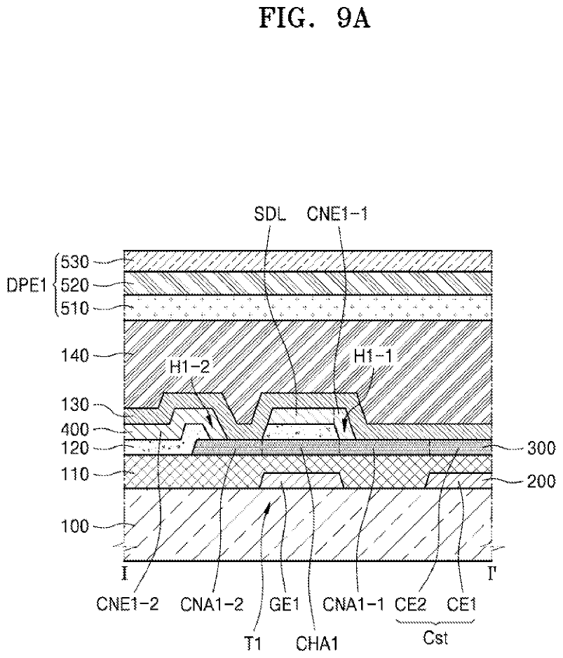

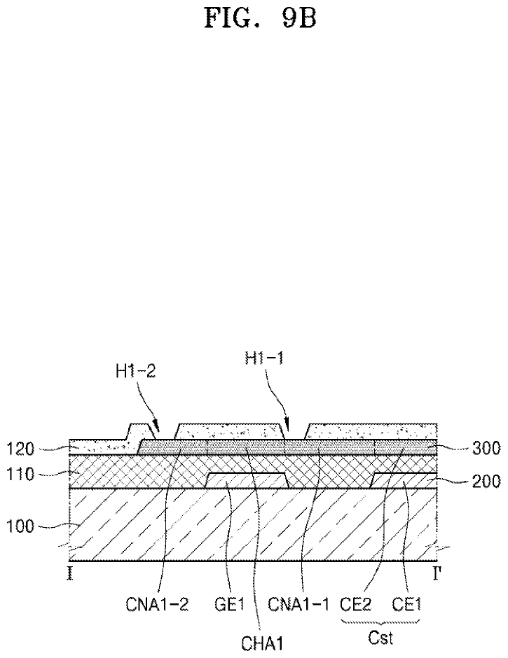

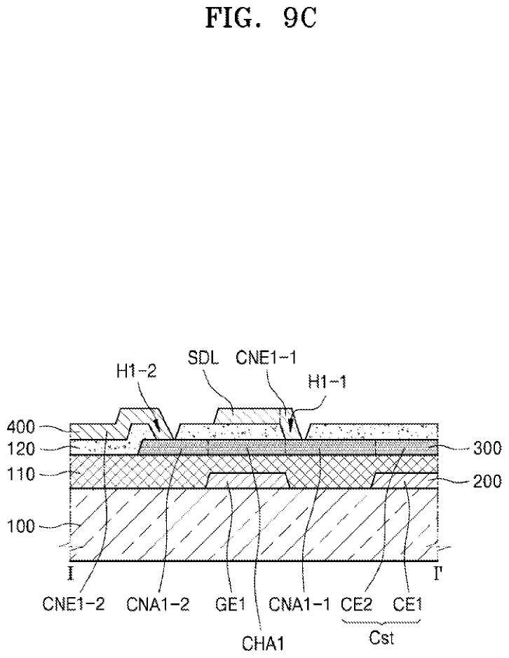

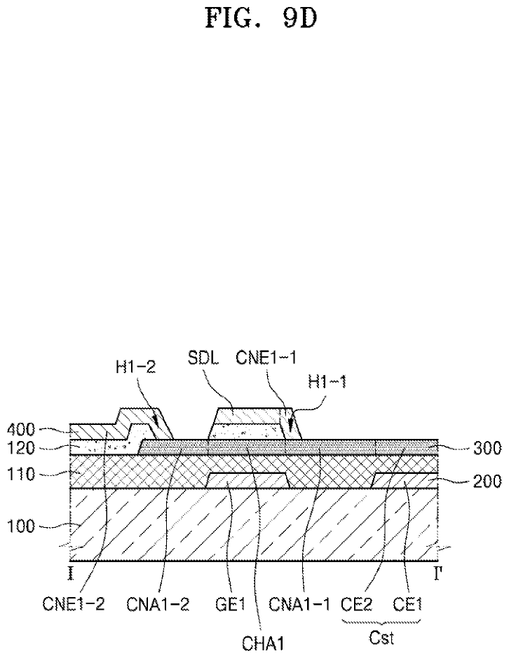

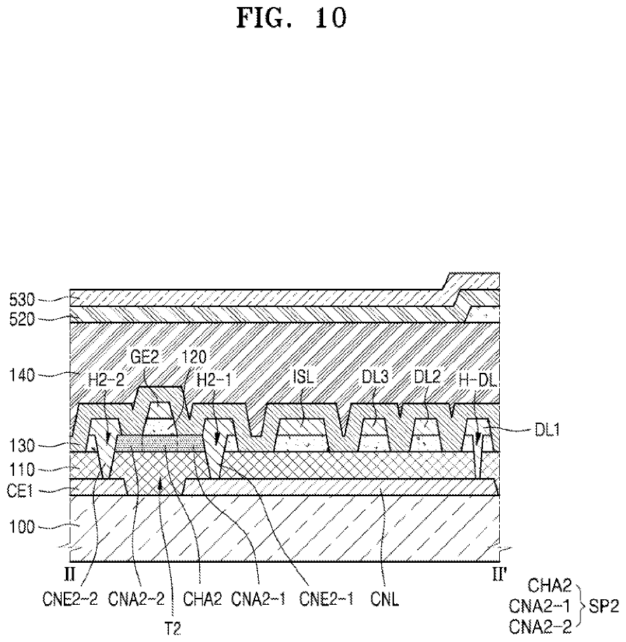

FIG. 4 is a schematic layout diagram illustrating respective locations of the first transistor T1, the second transistor T2, the third transistor T3, and the storage capacitor Cst in pixels included in the display apparatus 1 according to one or more embodiments, and FIGS. 5 through 8 are schematic layout diagrams illustrating respective components of the first transistor T1, the second transistor T2, the third transistor T3, and the storage capacitor Cst for each layer of the display apparatus 1 of FIG. 4. FIG. 9A is a schematic cross-sectional view illustrating a cross-section taken along the line I-I′ of the display apparatus 1 of FIG. 4, and FIG. 10 is a schematic cross-sectional view illustrating a cross-section taken along the line II-II′ of the display apparatus 1 of FIG. 4.

As shown in these drawings, the display apparatus 1 may include a first pixel, a second pixel, and a third pixel adjacent to one another. Thus, the first pixel may include a first pixel circuit PC1, the second pixel may include a second pixel circuit PC2, and the third pixel may include a third pixel circuit PC3. As shown in FIG. 4, the first pixel circuit PC1, the second pixel circuit PC2, and the third pixel circuit PC3 may be located adjacent to one another. The light-emitting panel 10 of the display apparatus 1 may include pixel circuits PC (such as, the first pixel circuit PC1, the second pixel circuit PC2, and the third pixel circuit PC3), the scan line SL, the control line CL, the data line DL, the initialization-sensing line ISL, the driving voltage line VDL, and the common voltage line VSL.

As described above, the first pixel may include the first pixel circuit PC1, the second pixel may include the second pixel circuit PC2, and the third pixel may include the third pixel circuit PC3. In other words the first pixel circuit PC1 may drive a first display element DPE1 of the first pixel, the second pixel circuit PC2 may drive a second display element of the second pixel, and the third pixel circuit PC3 may drive a third display element of the third pixel.

Each of the first pixel circuit PC1, the second pixel circuit PC2, and the third pixel circuit PC3 may include three transistors and one storage capacitor. In detail, the first pixel circuit PC1 may include a first transistor T1, a second transistor T2, a third transistor T3, and a storage capacitor Cst. Because the second pixel circuit PC2 and the third pixel circuit PC3 are similar to the first pixel circuit PC1, the first pixel circuit PC1 will now be focused on and described in detail for convenience of explanation.

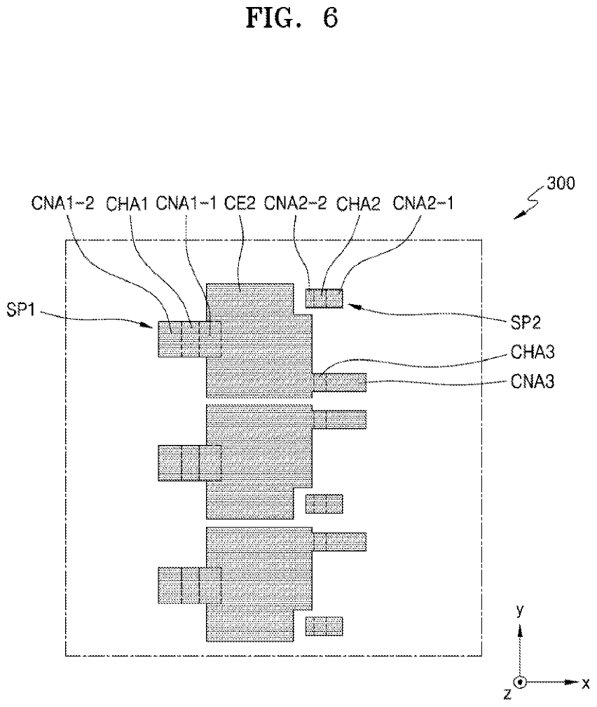

A buffer layer including silicon oxide, silicon nitride, or silicon oxynitride may be positioned on a substrate 100. The buffer layer may function to increase the smoothness of an upper surface of the substrate 100, and the buffer layer may reduce or prevent diffusion of metal atoms or impurities from the substrate 100 to an oxide semiconductor layer 300 (see FIG. 6) located on the metal atoms or the impurities. The buffer layer may be a single layer or multi-layer including silicon oxide, silicon nitride, or silicon oxynitride.

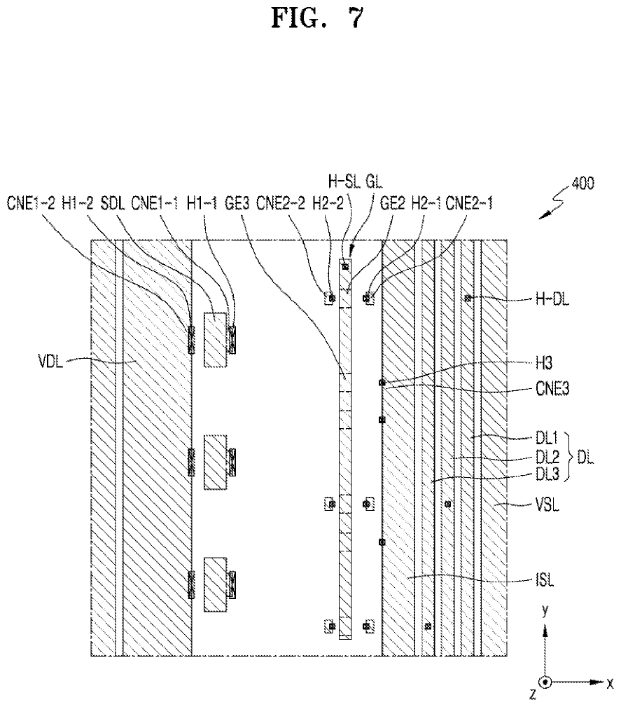

A first conductive layer 200 shown in FIG. 5 may be located on the substrate 100. The first conductive layer 200 may include the scan line SL and the control line CL each extending in a first direction (for example, an x-axis direction). Because the scan line SL may be electrically connected to a second gate electrode GE2 (see FIG. 7), an electrical signal may be applied to the second gate electrode GE2 via the scan line SL. The first conductive layer 200 may include a connection line CNL extending in the first direction (for example, the x-axis direction), and the connection line CNL may be electrically connected to the data line DL (see FIG. 7).

The first conductive layer 200 may further include a first gate electrode GE1 and a first capacitor electrode CE1. The first gate electrode GE1 and the first capacitor electrode CE1 may be integrated. In other words, the first gate electrode GE1 and the first capacitor electrode CE1 may be integrally formed with each other through the same process. Thus, the first gate electrode GE1 may include the same material as the first capacitor electrode CE1. The first gate electrode GE1 may have the same layer structure as the first capacitor electrode CE1. For example, when the first gate electrode GE1 has a double-layer structure, the first capacitor electrode CE1 may also have a double-layer structure formed of the same material as that used to form the first gate electrode GE1. Although the first gate electrode GE1 and the first capacitor electrode CE1 are integrated in FIG. 5, embodiments are not limited thereto. For example, the first capacitor electrode CE1 may be arranged apart from the first gate electrode GE1.

The first conductive layer 200 may include a metal, an alloy, a conductive metal oxide, or a transparent conductive material. For example, the first conductive layer 200 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first conductive layer 200 may have a multi-layered structure. For example, the first conductive layer 200 may have a double-layer structure of Mo/Al or a three-layered structure of Mo/Al/Mo.

A first insulating layer 110 of FIG. 9A may cover the first conductive layer 200 and may be located on (e.g., above) the substrate 100. The first insulating layer 110 may include an insulating material. For example, the first insulating layer 110 may include silicon oxide, silicon nitride, silicon oxynitride, or aluminum oxide.

The oxide semiconductor layer 300 shown in FIG. 6 may be located on the first insulating layer 110. The oxide semiconductor layer 300 may include a first semiconductor pattern SP1 and a second semiconductor pattern SP2. The first semiconductor pattern SP1 may include a first channel area CHA1, a third channel area CHA3, and a second capacitor electrode CE2, and the second semiconductor pattern SP2 may include a second channel area CHA2. The first channel area CHA1 may overlap the first gate electrode GE1.

In detail, the first semiconductor pattern SP1 may further include a first-first connection area CNA1-1 and a second-first connection area CNA1-2, and the first channel area CHA1 may be between the first-first connection area CNA1-1 and the second-first connection area CNA1-2. For example, the first-first connection area CNA1-1 may contact one side of the first channel area CHA1, the second-first connection area CNA1-2 may contact the other side of the first channel area CHA1, and the first channel area CHA1 may be integrated with the first-first connection area CNA1-1 and the second-first connection area CNA1-2.

The first-first connection area CNA1-1 and the second-first connection area CNA1-2 have different electrical properties from those of the first channel area CHA1, and thus may respectively correspond to a source region and a drain region. In detail the first channel area CHA1 may allow a current to flow only when a voltage is applied to a conductive layer located above or below the first channel area CHA1. However, even when a voltage is not applied to conductive layers located above or below the first-first connection area CNA1-1 and the second-first connection area CNA1-2, a current may flow in the first-first connection area CNA1-1 and the second-first connection area CNA1-2. In other words, a resistance of the first-first connection area CNA1-1 and a resistance of the second-first connection area CNA1-2, when no voltages are applied to the conductive layers located above or below the first-first connection area CNA1-1 and the second-first connection area CNA1-2, may be less than a resistance of the first channel area CHA1 when no voltages are applied to the conductive layer located above or below the first channel area CHA1.

The first semiconductor pattern SP1 may further include a third connection area CNA3, and the third channel area CHA3 may be located adjacent to the third connection area CNA3. For example, the third channel area CHA3 may be integrated with the third connection area CNA3. The third connection area CNA3 has different electrical properties from those of the third channel area CHA3, and may correspond to a source region or a drain region. In detail, the third channel area CHA3 may allow a current to flow when a voltage is applied to a conductive layer located above or below the third channel area CHA3. However, the third connection area CNA3 may allow a current to flow even when no voltages are applied to a conductive layer located above or below the third connection area CNA3. In other words, a resistance of the third connection area CNA3, when no voltages are applied to the conductive layer located above or below the third connection area CNA3, may be less than a resistance of the third channel area CHA3 when no voltages are applied to the conductive layer located above or below the third channel area CHA3.

The second capacitor electrode CE2 may be arranged between the first-first connection area CNA1-1 and the third channel area CHA3. For example, the first-first connection area CNA1-1 may contact one side of the second capacitor electrode CE2, the third channel area CHA3 may contact the other side of the second capacitor electrode CE2, and the second capacitor electrode CE2 may be integrated with the first-first connection area CNA1-1 and the third channel area CHA3. The first-first connection area CNA1-1 may correspond to a portion of the second capacitor electrode CE2. In other words, a portion of a portion of the second capacitor electrode CE2 that does not overlap the first capacitor electrode CE1 may correspond to the first-first connection area CNA1-1 of the first transistor T1. The second capacitor electrode CE2 may have different electrical properties from electrical properties of the first channel area CHA1. In contrast with the electrical properties of the first channel area CHA1, the second capacitor electrode CE2 may allow a current to flow even when no voltages are applied to a conductive layer located above or below the second capacitor electrode CE2. In other words, a resistance of the second capacitor electrode CE2, when no voltages are applied to the conductive layer located above or below the second capacitor electrode CE2, may be less than the resistance of the first channel area CHA1 when no voltages are applied to the conductive layer located above or below the first channel area CHA1. Thus, the second capacitor electrode CE2 may function as one electrode of the storage capacitor Cst.

The second semiconductor pattern SP2 may further include a first-second connection area CNA2-1 and a second-second connection area CNA2-2, and the second channel area CHA2 may be between the first-second connection area CNA2-1 and the second-second connection area CNA2-2. For example, the first-second connection area CNA2-1 may contact one side of the second channel area CHA2, the second-second connection area CNA2-2 may contact the other side of the second channel area CHA2, and the second channel area CHA2 may be integrated with the first-second connection area CNA2-1 and the second connection area CNA2-2.

The first-second connection area CNA2-1 and the second-second connection area CNA2-2 have different electrical properties from those of the second channel area CHA2, and thus may respectively correspond to a source region and a drain region. In detail, the second channel area CHA2 may allow a current to flow only when a voltage is applied to a conductive layer located above or below the second channel area CHA2. However, even when a voltage is not applied to conductive layers located above or below the first-second connection area CNA2-1 and the second-second connection area CNA2-2, a current may flow in the first-second connection area CNA2-1 and the second-second connection area CNA2-2. In other words, a resistance of the first-second connection area CNA2-1 and a resistance of the second-second connection area CNA2-2, when no voltages are applied to the conductive layers located above or below the first-second connection area CNA2-1 and the second-second connection area CNA2-2, may be less than a resistance of the second channel area CHA2 when no voltages are applied to the conductive layer located above or below the second channel area CHA2.

The oxide semiconductor layer 300 may include an oxide semiconductor. For example, the oxide semiconductor may include Zn oxide, In—Zn oxide, or Ga—In—Zn oxide, as a Zn oxide-based material. Alternatively, the oxide semiconductor may include an In-Ga—Zn-O (IGZO), In—Sn—Zn—O (ITZO), or In—Ga—Sn—Zn—O (IGTZO) containing metals, such as In, Ga, and Sn, in ZnO.

The first-first connection area CNA1-1, the second-first connection area CNA1-2, the first-second connection area CNA2-1, the second-second connection area CNA2-2, the third connection area CNA3, and the second capacitor electrode CE2 may be areas in which impurities are added to a layer formed of an oxide semiconductor. In other words, the first-first connection area CNA1-1, the second-first connection area CNA1-2, the first-second connection area CNA2-1, the second-second connection area CNA2-2, the third connection area CNA3, and the second capacitor electrode CE2 may be doped areas. Thus, the first-first connection area CNA1-1, the second-first connection area CNA1-2, the first-second connection area CNA2-1, the second-second connection area CNA2-2, the third connection area CNA3, and the second capacitor electrode CE2 may have different electrical properties from electrical properties of an undoped oxide semiconductor, for example, the first channel area CHA1, the second channel area CHA2, and the third channel area CHA3. In other words, a resistance of a doped area of the oxide semiconductor layer 300, when no voltages are applied to a conductive layer located above or below the doped area of the oxide semiconductor layer 300, may be less than a resistance of an undoped area of the oxide semiconductor layer 300 when no voltages are applied to the conductive layer located above or below the undoped area of the oxide semiconductor layer 300.

A second insulating layer 120 of FIG. 9A may cover the oxide semiconductor layer 300 and may be located on the first insulating layer 110. The second insulating layer 120 may include an insulating material. The second insulating layer 120 may include silicon oxide, silicon nitride, silicon oxynitride, or aluminum oxide.

A second conductive layer 400 shown in FIG. 7 may be located on the second insulating layer 120. The second conductive layer 400 may include the data line DL, the initialization-sensing line ISL, the driving voltage line VDL, and the common voltage line VSL. The data line DL, the initialization-sensing line ISL, the driving voltage line VDL, and the common voltage line VSL may each extend in a second direction (for example, a y-axis direction) intersecting the first direction. The data line DL may include a first data line DL1, a second data line DL2, and a third data line DL3. The first data line DL1, the second data line DL2, and the third data line DL3 may supply a data signal to the first pixel circuit PC1, the second pixel circuit PC2, and the third pixel circuit PC3, respectively.

The second conductive layer 400 may further include a gate wire GL, the second gate electrode GE2, and a third gate electrode GE3. The gate wire GL may be electrically connected to the scan line SL included in the first conductive layer 200. In detail, the gate wire GL may be electrically connected to the scan line SL through a scan line contact hole H-SL formed in the first insulating layer 110 and the second insulating layer 120.

The second gate electrode GE2 may overlap the second channel area CHA2. The second gate electrode GE2 may correspond to a portion of the gate wire GL. In other words, portions of the gate wire GL that overlap the oxide semiconductor layer 300 may correspond to respective gate electrodes of the respective second transistors T2 of the first pixel circuit PC1, the second pixel circuit PC2, and the third pixel circuit PC3, respectively. The third gate electrode GE3 may overlap the third channel area CHA3. The third gate electrode GE3 may correspond to a portion of the gate wire GL. The portions of the gate wire GL that overlap the oxide semiconductor layer 300 may correspond to respective gate electrodes of the respective third transistors T3 of the first pixel circuit PC1, the second pixel circuit PC2, and the third pixel circuit PC3, respectively. The gate wire GL may extend from the second direction (for example, the y-axis direction) between the driving voltage line VDL and the data line DL.

The second conductive layer 400 may further include a shielding layer SDL, a first-first connection electrode CNE1-1, a second-first connection electrode CNE1-2, a first-second connection electrode CNE2-1, a second-second connection electrode CNE2-2, and a third connection electrode CNE3. The shielding layer SDL may have a shape corresponding to the first channel area CHA1 of the first transistor T1 to protect the first channel area CHA1 overlapping the shielding layer SDL.

In detail, the first transistor T1 may have a bottom gate structure in which the first gate electrode GE1 is located below the first channel area CHA1. During a metallization process of the display apparatus 1 to be described later, the second gate electrode GE2 located above the second channel area CHA2 may function as a mask that covers the second channel area CHA2 such that the second channel area CHA2 is not metalized, and the third gate electrode GE3 located above the third channel area CHA3 may function as a mask that covers the third channel area CHA3 such that the third channel area CHA3 is not metalized. However, the first gate electrode GE1 may not function as a mask because the first gate electrode GE1 is located below the first channel area CHA1, and the shielding layer SDL located above the first channel area CHA1 may function as a mask that covers the first channel area CHA1 such that the first channel area CHA1 is not metalized. In other words, the shielding layer SDL may protect the first channel area CHA1. As used herein, “X is metalized” means that X including an oxide semiconductor has different electrical properties through plasma treatment. In other words, “X is metalized” means that the resistance of X after plasma treatment is lower than that of X before plasma treatment.

The first-first connection electrode CNE1-1 may be connected to the first-first connection area CNA1-1 of the first transistor T1 through a first-first contact hole H1-1 formed in the second insulating layer 120. The first-first connection electrode CNE1-1 may be integrated with the shielding layer SDL. Thus, the shielding layer SDL may be connected to the first-first connection electrode CNE1-1, and accordingly the first transistor T1 may have a source-sink structure. In other words, a source voltage may be applied to the shielding layer SDL located above the first channel area CHA1 of the first transistor T1.

Although the first-first connection electrode CNE1-1 is integrated with the shielding layer SDL in FIG. 7, embodiments are not limited thereto. The second-first connection electrode CNE1-2 may be connected to the second-first connection area CNA1-2 of the first transistor T1 through a second-first contact hole H1-2 formed in the second insulating layer 120. The second-first connection electrode CNE1-2 may correspond to a portion of the driving voltage line VDL.

The first-second connection electrode CNE2-1 may be connected to the first-second connection area CNA2-1 of the second transistor T2 through a first-second contact hole H2-1 formed in the first insulating layer 110 and the second insulating layer 120. The second-second connection electrode CNE2-2 may be connected to the second-second connection area CNA2-2 of the second transistor T2 through a second-second contact hole H2-2 formed in the first insulating layer 110 and the second insulating layer 120. The third connection electrode CNE3 may be connected to the third connection area CNA3 of the third transistor T3 through a third contact hole H3 formed in the second insulating layer 120.

The second conductive layer 400 may include a metal, an alloy, a conductive metal oxide, or a transparent conductive material. For example, the second conductive layer 400 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The second conductive layer 400 may have a multi-layered structure. For example, the second conductive layer 400 may have a double-layer structure of Mo/Al or a three-layered structure of Mo/Al/Mo.

A third insulating layer 130 of FIG. 9A may cover the second conductive layer 400 and may be located on (e.g., above) the second insulating layer 120. The third insulating layer 130 may include an insulating material. The third insulating layer 130 may include silicon oxide, silicon nitride, silicon oxynitride, or aluminum oxide. A fourth insulating layer 140 of FIG. 9A may be located on the third insulating layer 130 to cover the third insulating layer 130. The fourth insulating layer 140 may include an organic insulating material. For example, the fourth insulating layer 140 may include photoresist, benzocyclobutene (BCB), polyimide, hexamethyldisiloxane (HMDSO), polymethyl methacrylate (PMMA), polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, or a blend thereof.

The first display element DPE1 of FIG. 9A, for example, an organic light-emitting diode OLED, may be located on the fourth insulating layer 140. The first display element DPE1 may include a pixel electrode 510 of FIG. 9A, an intermediate layer 520 of FIG. 9A including an emission layer, and an opposite electrode 530 of FIG. 9A.

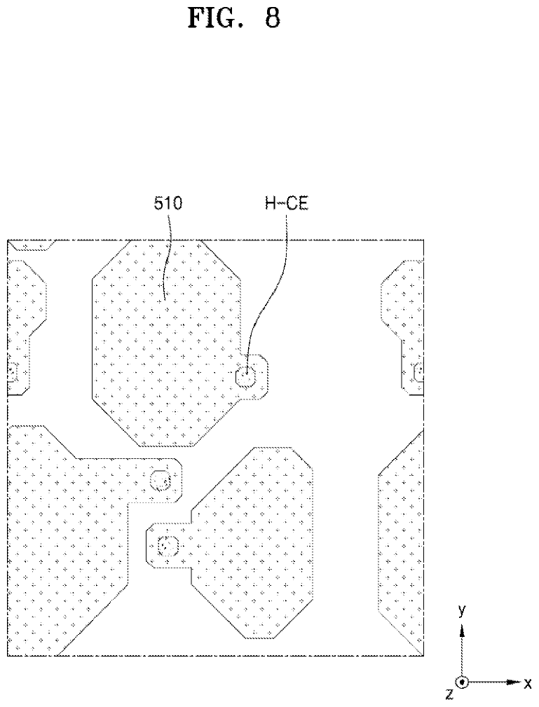

A pixel electrode 510 as shown in FIG. 8 may be located on or above the fourth insulating layer 140. The pixel electrode 510 may be electrically connected to the second capacitor electrode CE2 through a capacitor electrode contact hole H-CE formed in the third insulating layer 130 and the fourth insulating layer 140. Because the first display element DPE1 includes the pixel electrode 510, the first display element DPE1 may be electrically connected to the second capacitor electrode CE2 included in the oxide semiconductor layer 300.

The pixel electrode 510 may be a (semi) light-transmissive electrode or a reflective electrode. For example, the pixel electrode 510 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer located on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 510 may have a three-layered structure of ITO/Ag/ITO.

A pixel defining layer may be arranged on the fourth insulating layer 140. The pixel defining layer may reduce or prevent the likelihood of an electric arc or the like occurring on an edge of the pixel electrode 510 by increasing a distance between the edge of the pixel electrode 510 and an opposite electrode 530 over the pixel electrode 510. The pixel defining layer may be formed of at least one organic insulating material from among polyimide, polyamide, acryl resin, benzocyclobutene, and a phenolic resin, by using a method, such as spin coating.

At least a portion of the intermediate layer 520 of the first display element DPE1 may be located within an opening formed by the pixel defining layer. An emission region of the first display element DPE1 may be defined by the opening.

The intermediate layer 520 may include the emission layer. The emission layer may include an organic material including a fluorescent or phosphorescent material that emits red, green, blue, or white light. The emission layer may include a low molecular organic material or a high molecular organic material, and one or more functional layers, such as a hole transport layer (HTL), an hole injection layer (HIL), an electron transport layer (ETL), and an electron injection layer (EIL), may be further arranged below and above the emission layer.

The emission layer may have a shape patterned in correspondence with each pixel electrode 510. Various modifications may be made to the emission layer. For example, a layer other than the emission layer included in the intermediate layer 520 may be integrated to cover a plurality of pixel electrodes 510.

The opposite electrode 530 may be a light-transmissive electrode or a reflective electrode. For example, the opposite electrode 530 may be a transparent or semi-transparent electrode, and may include a metal thin film having a small work function, including Li, Ca, LiF, Al, Ag, Mg, or a combination thereof. The opposite electrode 530 may further include a transparent conductive oxide (TCO) layer of, for example, ITO, IZO, ZnO, or In₂O₃, located on the metal thin film. The opposite electrode 530 may be integrated to cover the entire surface of the display area DA, and may be located over the intermediate layer 520 and the pixel defining layer.

FIG. 9A is a schematic cross-sectional view taken along the line I-I′ of the display apparatus 1 of FIG. 4. As shown in FIG. 9A, the first gate electrode GE1 may be located below the oxide semiconductor layer 300. In other words, the first transistor T1 may have a bottom gate structure. Accordingly, the first insulating layer 110 may cover the first gate electrode GE1.

When a driving transistor has a top gate structure in which a gate electrode is located above a semiconductor layer, a pixel of a display apparatus may include an unwanted parasitic capacitance. As in the second pixel circuit PC2 of the second pixel of FIG. 4, a portion of a pixel electrode of another pixel of a display apparatus may be located on a pixel circuit of one pixel of the display apparatus. When a driving transistor has a top gate structure, a portion of a pixel electrode of another pixel may be located on a gate electrode of a driving transistor of one pixel. In this case, a parasitic capacitance may be formed between the gate electrode of the driving transistor of the one pixel and the pixel electrode of the other pixel. The parasitic capacitance may affect a voltage of the gate electrode of the one pixel. In other words, even when a voltage different from a preset voltage is applied to the gate electrode of the driving transistor of the one pixel or the preset voltage is applied, the voltage of the gate electrode of the driving transistor may not be maintained constant. Accordingly, the organic light-emitting diode OLED may emit light of unintended brightness, and thus may not display a high-quality image.

However, in the case of the display apparatus 1 according to one or more embodiments, the driving transistor, for example, the first gate electrode GE1, may be located below the oxide semiconductor layer 300, and the first insulating layer 110 may cover the first gate electrode GE1. Thus, even when the pixel electrode 510 of the other pixel is located on the pixel circuit PC of the one pixel of the display apparatus 1, a parasitic capacitance may not be formed between the first gate electrode GE1 of the first transistor T1 of the one pixel and the pixel electrode 510 of the other pixel. Thus, a voltage of the first gate electrode GE1 may not be affected by the parasitic capacitance, or an influence of the parasitic capacitance upon the voltage of the first gate electrode GE1 may be reduced or minimized. In other words, an electrical signal may be stably applied to the first gate electrode GE1. Thus, brightness of the organic light-emitting diode OLED may be appropriately controlled.

A reason why a cross-section as shown in FIG. 9A is obtained will be described with reference to FIGS. 9B, 9C, and 9D. FIGS. 9B, 9C, and 9D are schematic cross-sectional views of a process of manufacturing a portion of the display apparatus 1 of FIG. 4.

First, as shown in FIG. 9B, the first conductive layer 200 including the first gate electrode GE1 and the first capacitor electrode CE1 may be formed above the substrate 100, and the first insulating layer 110 may be formed to cover the first conductive layer 200. Because the first insulating layer 110 covers the first conductive layer 200 to correspond to the entire surface of the substrate 100, the first insulating layer 110 may cover the first gate electrode GE1 and the first capacitor electrode CE1 included in the first conductive layer 200. The first semiconductor pattern SP1 including the first channel area CHA1, the first-first connection area CNA1-1, and the second-first connection area CNA1-2 may be formed above the first insulating layer 110. The second insulating layer 120 may be formed above the first semiconductor pattern SP1. Thereafter, as shown in FIG. 9B, the first-first contact hole H1-1 and the second-first contact hole H1-2 penetrating through the second insulating layer 120 may be formed. The first-first contact hole H1-1 may be formed to overlap the first-first connection area CNA1-1 in a plan view, and the second-first contact hole H1-2 may be formed to overlap the second-first connection area CNA1-2 in a plan view.

Then, as shown in FIG. 9C, after a preliminary second conductive layer may be formed on the second insulating layer 120 to cover the second insulating layer 120, the second conductive layer 400 may be patterned. Thus, the second conductive layer 400 including the first-first connection electrode CNE1-1 and the second-first connection electrode CNE1-2 may be formed. In this case, the first-first contact hole H1-1 and the second-first contact hole H1-2 penetrating through the second insulating layer 120 may be filled with a portion of the second conductive layer 400. Thus, the first-first connection electrode CNE1-1 may be electrically connected to the first-first connection area CNA1-1 via the first-first contact hole H1-1, and the second-first connection electrode CNE1-2 may be electrically connected to the second-first connection area CNA1-2 via the second-first contact hole H1-2.

Then, as shown in FIG. 9D, a portion of the second insulating layer 120 that includes no second conductive layers 400 formed thereon may be removed. In other words, the second insulating layer 120 may be located only below the second conductive layer 400. Thus, the second insulating layer 120 may exist below the shielding layer SDL, the first-first connection electrode CNE1-1, and the second-first connection electrode CNE1-2, and there may be no second insulating layers 120 existing below the outside of the first-first connection electrode CNE1-1 and the outside of the second-first connection electrode CNE1-2.

Thus, FIGS. 9B and 9C illustrate the first-first contact hole H1-1 and the second-first contact hole H1-2 in shapes, such as holes in a plan view. However, in FIG. 9D, portions of the second insulating layer 120 on the outside of the first-first connection electrode CNE1-1 and the outside of the second-first connection electrode CNE1-2 are removed, and thus the first-first contact hole H1-1 and the second-first contact hole H1-2 do not appear in shapes, such as holes in a plan view. Accordingly, the display apparatus 1 according to one or more embodiments may have a cross-section as in FIG. 9A.

FIG. 10 is a schematic cross-sectional view taken along the line II-II′ of the display apparatus 1 of FIG. 4. As shown in FIG. 10, the first-second connection electrode CNE2-1 of the second transistor T2 may be electrically connected to the first-second connection area CNA2-1 of the second transistor T2. The first-second connection electrode CNE2-1 of the second transistor T2 may be electrically connected to the connection line CNL.

In detail, the first-second connection electrode CNE2-1 may be connected to the connection line CNL through the first-second contact hole H2-1 formed in the first insulating layer 110 and the second insulating layer 120. Because the first-second connection electrode CNE2-1 may be connected to the first-second connection area CNA2-1, the first-second connection area CNA2-1 and the connection line CNL may be connected to each other via the first-second connection electrode CNE2-1. In other words, the first-second connection electrode CNE2-1 may serve as a bridge that connects the first-second connection area CNA2-1 to the connection line CNL. Because the connection line CNL is electrically connected to the first data line DL1 via a data line contact hole H-DL, the first-second connection electrode CNE2-1 of the second transistor T2 may be electrically connected to the first data line DL1.

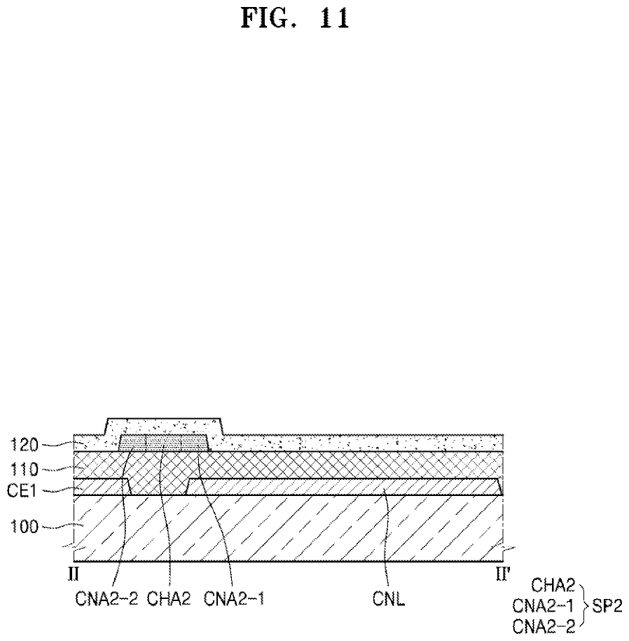

FIGS. 11 through 14 are schematic cross-sectional views illustrating a process of manufacturing a portion of the display apparatus 1 of FIG. 4. In detail, FIGS. 11 through 14 are schematic cross-sectional views illustrating a process of manufacturing the connection line CNL, the first-second connection area CNA2-1, and the first-second connection electrode CNE2-1 of the display apparatus 1 of FIG. 1.

First, as shown in FIG. 11, the connection line CNL and the first capacitor electrode CE1 may be formed above the substrate 100, and the first insulating layer 110 may be formed to cover the connection line CNL and the first capacitor electrode CE1. Because the first insulating layer 110 covers the first conductive layer 200 to correspond to the entire surface of the substrate 100, the first insulating layer 110 may cover the connection line CNL and the first capacitor electrode CE1 included in the first conductive layer 200. The second semiconductor pattern SP2 including the second channel area CHA2, the first-second connection area CNA2-1, and the second-second connection area CNA2-2 may be formed above the first insulating layer 110. The second insulating layer 120 may be formed above the second semiconductor pattern SP2.

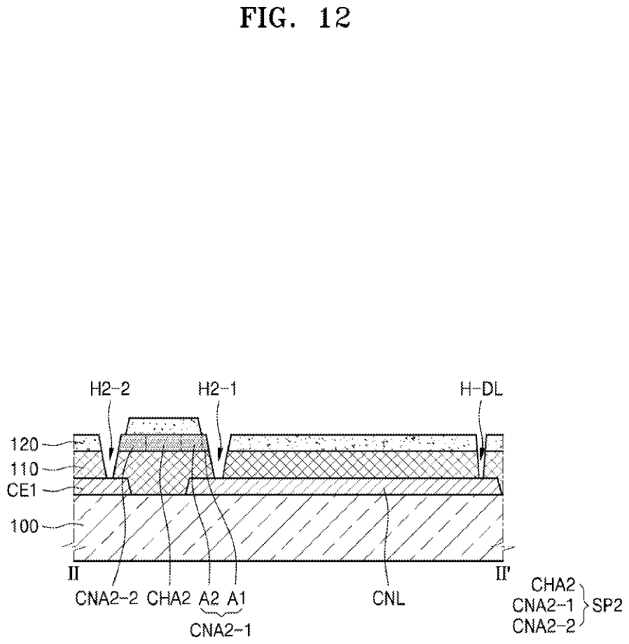

Then, as shown in FIG. 12, the first-second contact hole H2-1, the second-second contact hole H2-2, and the data line-contact hole H-DL penetrating through the first insulating layer 110 and the second insulating layer 120 may be formed. The first-second contact hole H2-1 may be formed to overlap the first-second connection area CNA2-1 and the connection line CNL in a plan view. In detail, a portion of the first-second contact hole H2-1 may overlap the first-second connection area CNA2-1 in a plan view, and the entirety of the first-second contact hole H2-1 may overlap the connection line CNL in a plan view. The second-second contact hole H2-2 may be formed to overlap the second-second connection area CNA2-2 and the first capacitor electrode CE1 in a plan view. The data line-contact hole H-DL may be formed to overlap the connection line CNL in a plan view.

The first-second connection area CNA2-1 may include the first area A1 and the second area A2, the first area A1 may be a portion of the first-second connection area CNA2-1 exposed by the first-second contact hole H2-1, and the second area A2 may be a portion of the first-second connection area CNA2-1 not exposed by the first-second contact hole H2-1. The first area A1 exposed by the first-second contact hole H2-1 may be metalized via plasma processing or the like. In detail, the first-second contact hole H2-1 may be formed by using plasma, and the first area A1 of the first-second connection area CNA2-1 may be plasma-processed during formation of the first-second contact hole H2-1.

For example, plasma processing may be chemically or materially modifying the surface of a material due to collision of high energy particles placed in a plasma state with the surface of the material. In the plasma processing, at least one gas selected from the group consisting of hydrogen gas, argon gas, helium gas, xenon gas, nitrogen gas, nitrogen oxide gas, oxygen gas, and a mixed gas thereof may be used.

When an oxide semiconductor is plasma-processed, the oxide semiconductor is reduced, and thus oxygen defects included in the oxide semiconductor may be induced and oxygen vacancy may increase. In an oxide semiconductor having an increased oxygen vacancy, the concentration of carriers is increased, and as a result, the concentration of a threshold voltage, which is a voltage through which electricity is passed from among semiconductor characteristics, may shift in a negative direction. This may mean that the oxide semiconductor is metalized to conduct electricity well. In other words, electrical characteristics of the oxide semiconductor before plasma processing may be different from those of the oxide semiconductor after plasma processing. For example, the resistance of the oxide semiconductor after plasma processing may be lower than the resistance of the oxide semiconductor before plasma processing. Thus, because the first-second contact hole H2-1 is formed by using plasma, the first area A1 of the first-second connection area CNA2-1 exposed by the first-second contact hole H2-1 may be plasma-processed. Accordingly, the first area A1 may be metalized.

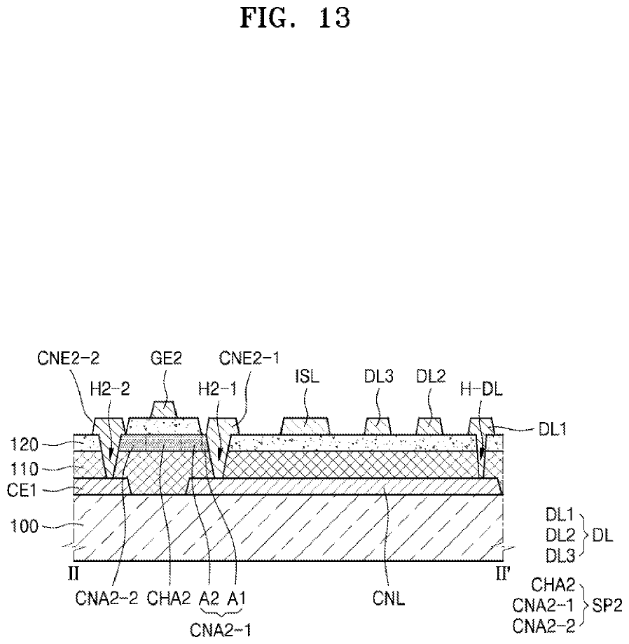

Then, as shown in FIG. 13, the second gate electrode GE2, the first-second connection electrode CNE2-1, the second-second connection electrode CNE2-2, the initialization-sensing line ISL, and the data line DL may be formed on the second insulating layer 120. In detail, a portion of the first-second connection electrode CNE2-1 may contact the first area A1 of the first-second connection area CNA2-1, and a portion of the first-second connection electrode CNE2-1 may contact the connection line CNL. Accordingly, as described above, the first-second connection electrode CNE2-1 may serve as a bridge that connects the first-second connection area CNA2-1 to the connection line CNL. The first-second connection electrode CNE2-1 may not overlap the second area A2 of the first-second connection area CNA2-1 in a plan view.

The above-described shielding layer SDL may be formed through the same process as the second gate electrode GE2. Thus, the shielding layer SDL may include the same material as the second gate electrode GE2. The shielding layer SDL may have the same layer structure as the second gate electrode GE2. For example, when the second gate electrode GE2 has a double-layer structure, the shielding layer SDL may also have a double-layer structure formed of the same material as that used to form the second gate electrode GE2.

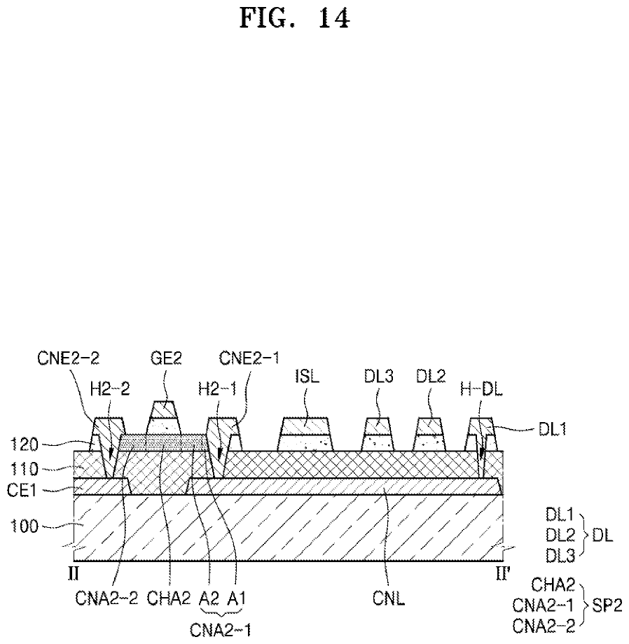

Then, as shown in FIG. 14, a portion of the second insulating layer 120 having no second conductive layers 400 formed thereabove may be removed. In other words, the second insulating layer 120 may be located only below the second conductive layer 400 (e.g., after other portions thereof are removed). Thus, the second insulating layer 120 may exist below the second gate electrode GE2, the first-second connection electrode CNE2-1, and the second-second connection electrode CNE2-2, but the second insulating layer 120 may not exist on the second area A2 of the first-second connection area CNA2-1. Outside the first-second connection area CNA2-1, the second insulating layer 120 may exist below the second gate electrode GE2, the first-second connection electrode CNE2-1, the second-second connection electrode CNE2-2, the initialization-sensing line ISL, and the data line DL. In other words, outside the first-second connection area CNA2-1, the second insulating layer 120 may be interposed between the first insulating layer 110 and the second conductive layer 400.

A portion of the second insulating layer 120 having no second conductive layers 400 formed thereabove may be removed using plasma. Thus, a portion of the oxide semiconductor layer 300 existing below the removed portion of the second insulating layer 120, for example, the second area A2 of the first-second connection area CNA2-1, may be metalized by plasma processing. Thus, the first-second connection area CNA2-1 including the first area A1 and the second area A2 may be metalized. In other words, electrical properties of the first-second connection area CNA2-1 may be different from electrical properties of the second channel area CHA2.

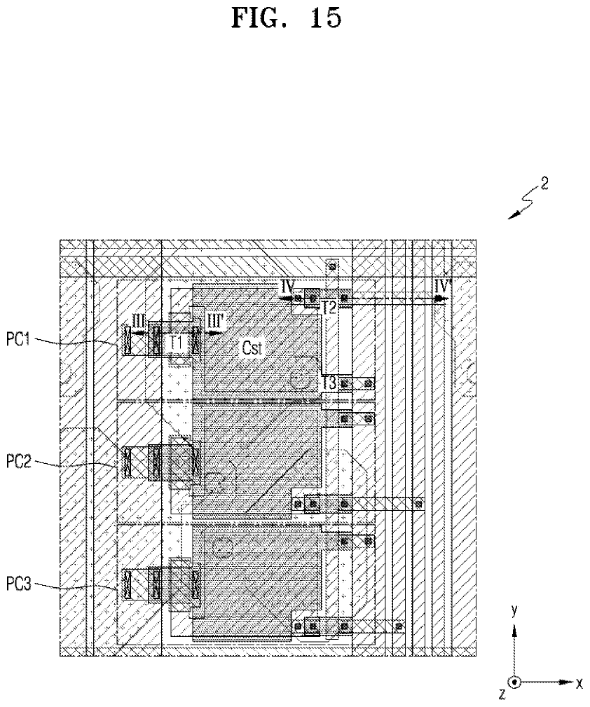

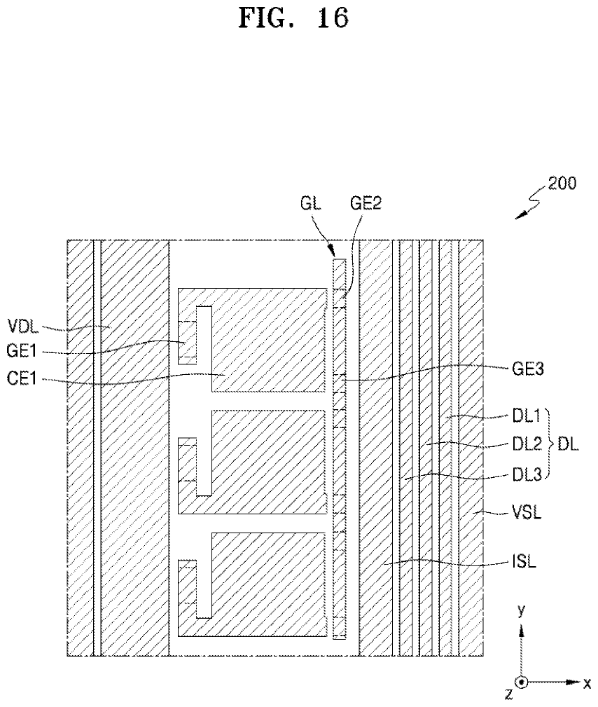

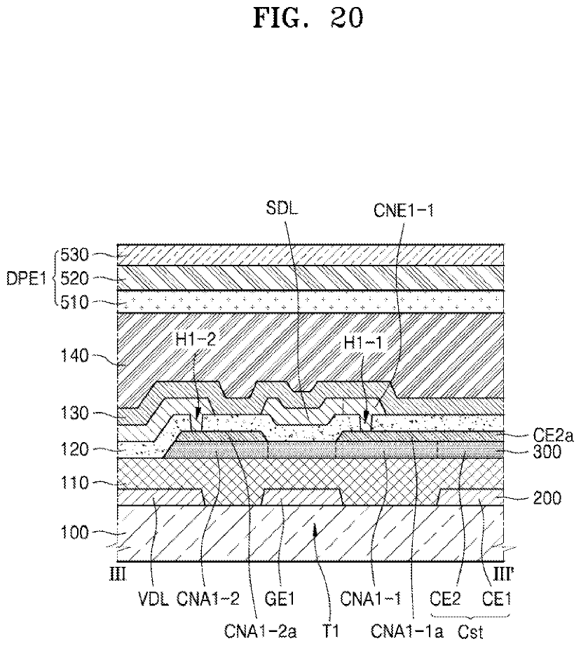

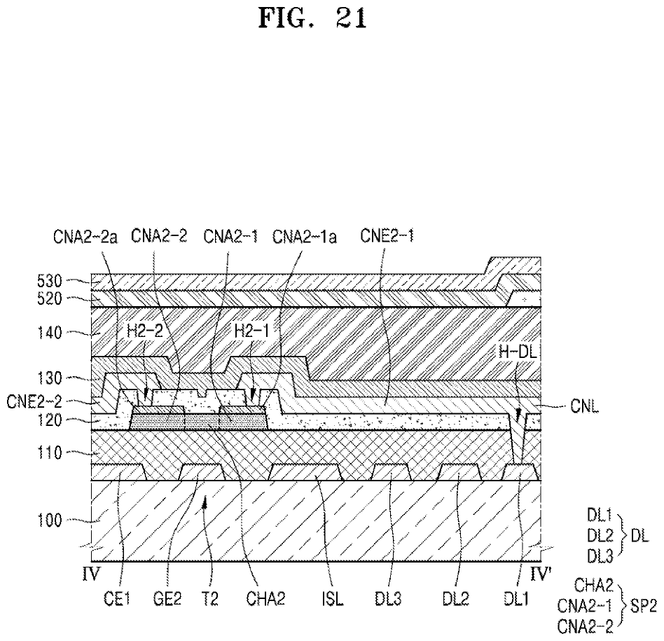

FIG. 15 is a schematic layout diagram illustrating respective locations of a first transistor T1, a second transistor T2, a third transistor T3, and a storage capacitor Cst in pixels included in a display apparatus 2 according to one or more other embodiments, and FIGS. 16 through 19 are schematic layout diagrams illustrating respective components of the first transistor T1, the second transistor T2, the third transistor T3, and the storage capacitor Cst for each layer of the display apparatus 2 of FIG. 15. FIG. 20 is a schematic cross-sectional view illustrating a cross-section taken along the line III-III′ of the display apparatus 2 of FIG. 15, and FIG. 21 is a schematic cross-sectional view illustrating a cross-section taken along the line IV-IV′ of the display apparatus 2 of FIG. 15. Because the display apparatus 2 according to one or more embodiments is similar to the display apparatus 1 described above with reference to FIGS. 1 through 14, a difference of the display apparatus 2 from the display apparatus 1 described above with reference to FIGS. 1 through 14 will now be focused on and described.

A first conductive layer 200 shown in FIG. 16 may be located on a substrate 100. The first conductive layer 200 included in the display apparatus 1 according to the embodiments described above with reference to FIG. 5 and the like include the control line CL, the scan line SL, the connection line CNL, the first gate electrode GE1, and the first capacitor electrode CE1. The first conductive layer 200 included in the display apparatus 2 according to one or more embodiments may also include the first gate electrode GE1 and the first capacitor electrode CE1. However, in the display apparatus 2 according to one or more embodiments, the first conductive layer 200 does not include a control line CL, a scan line SL, and a connection line CNL, whereas the first conductive layer 200 may include a data line DL, an initialization-sensing line ISL, a driving voltage line VDL, a common voltage line VSL, and a gate wire GL.

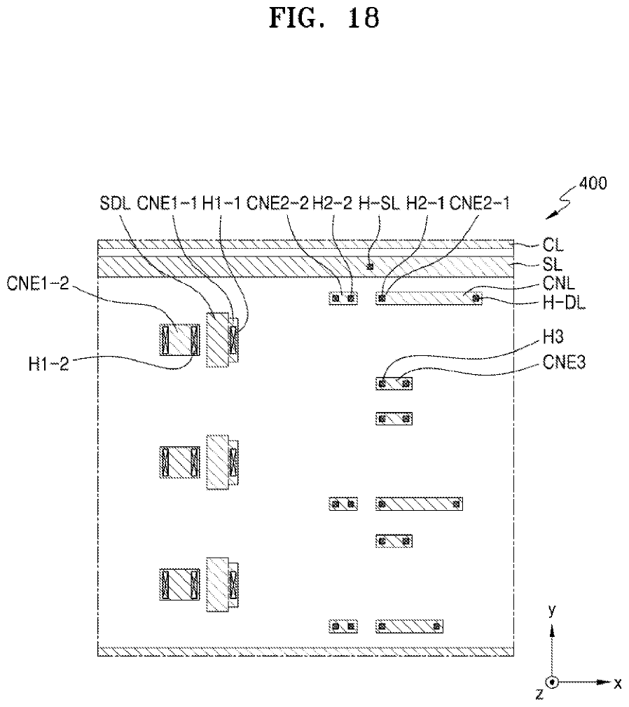

The data line DL, the initialization-sensing line ISL, the driving voltage line VDL, and the common voltage line VSL may each extend in the second direction (for example, the y-axis direction). The data line DL may include a first data line DL1, a second data line DL2, and a third data line DL3. The first data line DL1, the second data line DL2, and the third data line DL3 may supply a data signal to a first pixel circuit PC1, a second pixel circuit PC2, and a third pixel circuit PC3, respectively. The gate wire GL may be electrically connected to a scan line SL included in a second conductive layer 400. In detail, the gate wire GL may be electrically connected to the scan line SL through a scan line contact hole H-SL of FIG. 18 formed in a first insulating layer 110 of FIG. 20 and a second insulating layer 120 of FIG. 20.

The first conductive layer 200 may further include the first gate electrode GE1, the first capacitor electrode CE1, the gate wire GL, a second gate electrode GE2, and a third gate electrode GE3. The first insulating layer 110 may cover the first conductive layer 200 and may be located on the substrate 100.

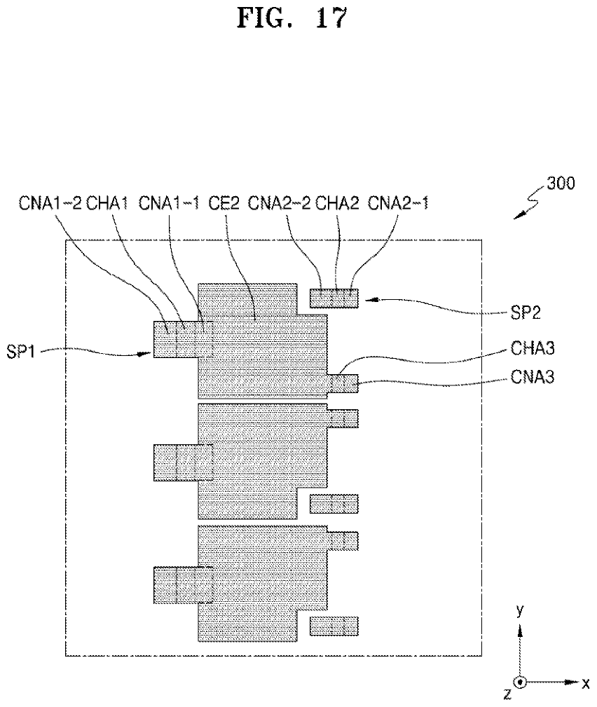

An oxide semiconductor layer 300 as shown in FIG. 17 may be located on the first insulating layer 110. The oxide semiconductor layer 300 may include a first channel area CHA1, a second channel area CHA2, a third channel area CHA3, and a second capacitor electrode CE2. The first channel area CHA1 may overlap the first gate electrode GE1, the second channel area CHA2 may overlap the second gate electrode GE2, and the third channel area CHA3 may overlap the third gate electrode GE3.

Compared with the above-described display apparatus 1, a first-first connection area CNA1-1, a second-first connection area CNA1-2, a first-second connection area CNA2-1, a second-second connection area CNA2-2, a third connection area CNA3, and the second capacitor electrode CE2 according to one or more embodiments may be a layer formed of a non-metalized oxide semiconductor. Connection metal layers may be located on the first-first connection area CNA1-1, the second-first connection area CNA1-2, the first-second connection area CNA2-1, the second-second connection area CNA2-2, and/or the third connection area CNA3, respectively. A capacitor metal layer may be located on the second capacitor electrode CE2.

In detail, the connection metal layer corresponding to the first-first connection area CNA1-1 may be located on the first-first connection area CNA1-1, and the connection metal layer corresponding to the second-first connection area CNA1-2 may be located on the second-first connection area CNA1-2. The connection metal layer corresponding to the first-second connection area CNA2-1 may be located on the first-second connection area CNA2-1, and the connection metal layer corresponding to the second-second connection area CNA2-2 may be located on the second-second connection area CNA2-2. The connection metal layer corresponding to the third connection area CNA3 may be located on the third connection area CNA3. A capacitor metal layer corresponding to the second capacitor electrode CE2 may be located on the second capacitor electrode CE2.

The connection metal layer and/or the capacitor metal layer may be a metal layer including a metal, such as titanium (Ti), molybdenum (Mo), or tungsten (W). The connection metal layer and/or the capacitor metal layer may have a single-layered or multi-layered structure including the aforementioned metal. For example, the connection metal layer and/or the capacitor metal layer may have a single layered structure, such as a titanium layer, a molybdenum layer, or a tungsten layer. Alternatively, the connection metal layer and/or the capacitor metal layer may have a multi-layered structure in which the aforementioned layers are stacked. The second insulating layer 120 may cover the oxide semiconductor layer 300 and the connection metal layer and/or the capacitor metal layer, and may be located on the first insulating layer 110.

During the above-described metallization process of the display apparatus 1, the second gate electrode GE2 located above the second channel area CHA2 may function as a mask that covers the second channel area CHA2 such that the second channel area CHA2 is not metalized, and the third gate electrode GE3 located above the third channel area CHA3 may function as a mask that covers the third channel area CHA3 such that the third channel area CHA3 is not metalized. However, the display apparatus 2 according to one or more embodiments, the second gate electrode GE2 may not function as a mask because the second gate electrode GE2 is located below the second channel area CHA2, and the third gate electrode GE3 may not function as a mask either because the third gate electrode GE3 is located below the third channel area CHA3. Thus, connection metal layers are located on the non-metalized first-first connection area CNA1-1, the non-metalized second-first connection area CNA1-2, the non-metalized first-second connection area CNA2-1, the non-metalized second-second connection area CNA2-2, and/or the non-metalized third connection area CNA3, respectively, so that there may be generated the same effect as when the first-first connection area CNA1-1, the second-first connection area CNA1-2, the first-second connection area CNA2-1, the second-second connection area CNA2-2, and/or the third connection area CNA3 are metalized. Even when the capacitor metal layer corresponding to the second capacitor electrode CE2 is located on the second capacitor electrode CE2, the same effect as when the second capacitor electrode CE2 is metalized may be generated.

A second conductive layer 400 as shown in FIG. 18 may be located on the second insulating layer 120. The second conductive layer 400 included in the display apparatus 1 according to the embodiments described above with reference to FIG. 5 and others include the data line DL, the initialization-sensing line ISL, the driving voltage line VDL, the common voltage line VSL, the gate wire GL, the shielding layer SDL, the first-first connection electrode CNE1-1, the second-first connection electrode CNE1-2, the first-second connection electrode CNE2-1, the second-second connection electrode CNE2-2, and the third connection electrode CNE3. The second conductive layer 400 included in the display apparatus 2 according to one or more embodiments also includes the shielding layer SDL, the first-first connection electrode CNE1-1, the second-first connection electrode CNE1-2, the first-second connection electrode CNE2-1, the second-second connection electrode CNE2-2, and the third connection electrode CNE3. However, in the display apparatus 2 according to one or more embodiments, the second conductive layer 400 may not include the data line DL, the initialization-sensing line ISL, the driving voltage line VDL, the common voltage line VSL, and the gate wire GL, whereas the second conductive layer 400 may include the control line CL, the scan line SL, and the connection line CNL.

The second conductive layer 400 may include the scan line SL and the control line CL each extending in the first direction (for example, the x-axis direction). The second conductive layer 400 may include the connection line CNL extending in the first direction (for example, the x-axis direction).

The first-second connection electrode CNE2-1 and the connection line CNL may be integrated. In other words, the first-second connection electrode CNE2-1 and the connection line CNL may be integrally formed with each other through the same process. For example, the first-second connection electrode CNE2-1 may be a portion of the connection line CNL. Thus, the first-second connection electrode CNE2-1 may include the same material as the connection line CNL. The first-second connection electrode CNE2-1 may have the same layer structure as the connection line CNL. For example, when the first-second connection electrode CNE2-1 has a double-layer structure, the connection line CNL may also have a double-layer structure formed of the same material as that used to form the first-second connection electrode CNE2-1.

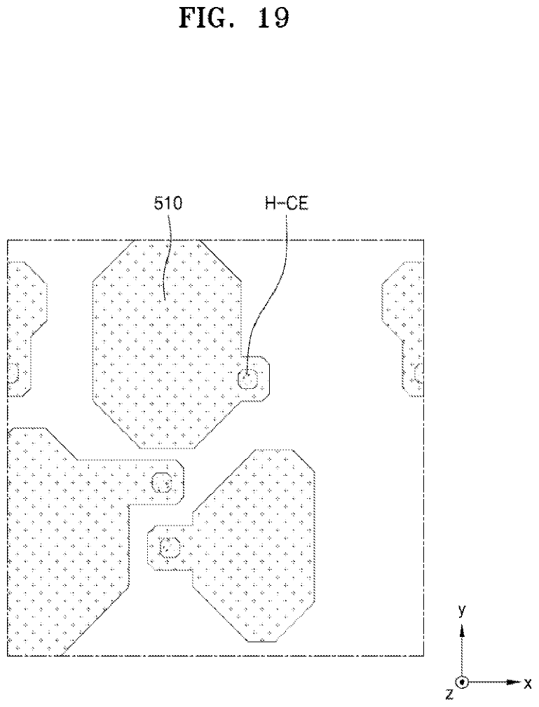

A third insulating layer 130 of FIG. 20 may cover the second conductive layer 400 and may be located on the second insulating layer 120. A fourth insulating layer 140 of FIG. 20 may be located on the third insulating layer 130 to cover the third insulating layer 130. A first display element DPE1 may be located on the fourth insulating layer 140. The first display element DPE1 may include a pixel electrode 510, an intermediate layer 520 including an emission layer, and an opposite electrode 530, and the pixel electrode 510 of FIG. 19 may be located on the fourth insulating layer 140.

FIG. 20 is a schematic cross-sectional view taken along the line III-III′ of the display apparatus 2 of FIG. 15. Similar to the above-described display apparatus 1, the first gate electrode GE1 of the display apparatus 2 may also be located below the oxide semiconductor layer 300. In other words, the first transistor T1 of the display apparatus 2 may have a bottom gate structure. Accordingly, the first insulating layer 110 may cover the first gate electrode GE1. An effect generated due to a location of the first gate electrode GE1 below the oxide semiconductor layer 300 and due to covering of the first gate electrode GE1 by the first insulating layer 110 may also occur in the case of the display apparatus 2. Thus, a description of an effect generated due to a location of the first gate electrode GE1 of the display apparatus 2 below the oxide semiconductor layer 300 and due to covering of the first gate electrode GE1 by the first insulating layer 110, which is the same as given above, will not be repeated herein. A first-first connection metal layer CNA1-1a may be located on the first-first connection area CNA1-1, a second-first connection metal layer CNA1-2a may be located on the second-first connection area CNA1-2, and a second capacitor metal layer CE2a may be located on the second capacitor electrode CE2.

FIG. 21 is a schematic cross-sectional view taken along the line IV-IV′ of the display apparatus 2 of FIG. 15. As shown in FIG. 21, the first-second connection electrode CNE2-1 of the second transistor T2 may be electrically connected to a connection metal layer on the first-second connection area CNA2-1 of the second transistor T2. Accordingly, the first-second connection electrode CNE2-1 of the second transistor T2 may be electrically connected to the first-second connection area CNA2-1 of the second transistor T2. The first-second connection electrode CNE2-1 of the second transistor T2 may be integrated with the connection line CNL. Because the connection line CNL is electrically connected to the first data line DL1, the first-second connection electrode CNE2-1 of the second transistor T2 may be electrically connected to the first data line DL1.

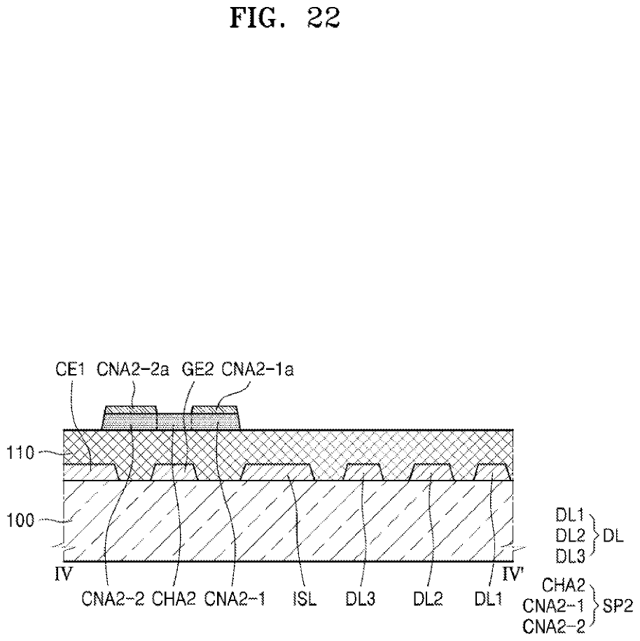

FIGS. 22 through 24 are schematic cross-sectional views illustrating a process of manufacturing a portion of the display apparatus 2 of FIG. 15. In detail, FIGS. 22 through 24 are schematic cross-sectional views illustrating a process of manufacturing the connection line CNL, the first-second connection area CNA2-1, the connection metal layer on the first-second connection area CNA2-1, and the first-second connection electrode CNE2-1 of the display apparatus 2 of FIG. 15.

First, as shown in FIG. 22, the first capacitor electrode CE1, the second gate electrode GE2, the initialization-sensing line ISL, and the data line DL may be formed above the substrate 100, and the first insulating layer 110 may be formed to cover the first capacitor electrode CE1, the second gate electrode GE2, the initialization-sensing line ISL, and the data line DL. Because the first insulating layer 110 covers the first conductive layer 200 to correspond to the entire surface of the substrate 100, the first insulating layer 110 may cover the first capacitor electrode CE1, the second gate electrode GE2, the initialization-sensing line ISL, and the data line DL included in the first conductive layer 200.

The above-described first gate electrode GE1 may be formed through the same process as the second gate electrode GE2. Thus, the first gate electrode GE1 may include the same material as the second gate electrode GE2. The first gate electrode GE1 may have the same layer structure as the second gate electrode GE2. For example, when the second gate electrode GE2 has a double-layer structure, the first gate electrode GE1 may also have a double-layer structure formed of the same material as that used to form the second gate electrode GE2.

A second semiconductor pattern SP2 may be formed above the first insulating layer 110. A first-second connection metal layer CNA2-1a corresponding to the first-second connection area CNA2-1 may be formed on the first-second connection area CNA2-1, and a second-second connection metal layer CNA2-2a corresponding to the second-second connection area CNA2-2 may be formed on the second-second connection area CNA2-2. To this end, after a preliminary oxide semiconductor layer is formed on the first insulating layer 110 and a preliminary connection metal layer is formed on the preliminary oxide semiconductor layer, the preliminary oxide semiconductor layer and the preliminary connection metal layer may be concurrently or substantially simultaneously patterned using a photoresist. In detail, during exposure of the photoresist, the preliminary oxide semiconductor layer and the preliminary connection metal layer may be concurrently or substantially simultaneously patterned by using a halftone mask.

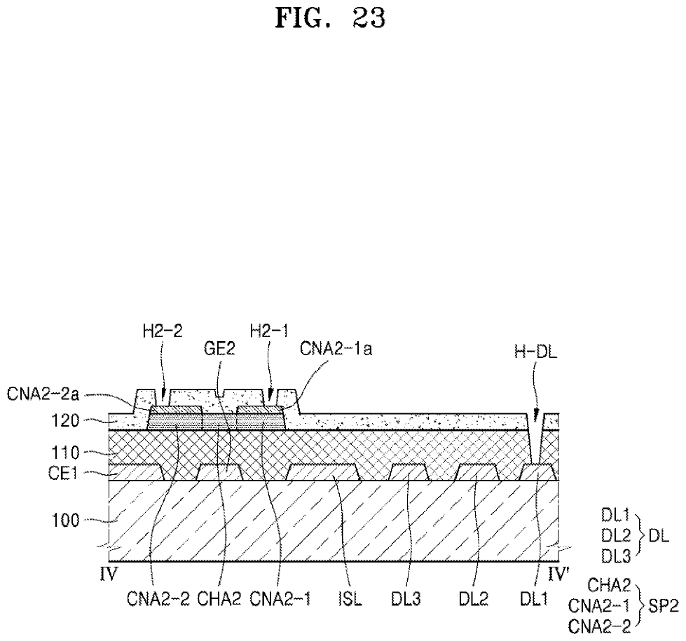

Then, as shown in FIG. 23, the second insulating layer 120 may be formed above the second semiconductor pattern SP2, and a first-second contact hole H2-1 penetrating through the second insulating layer 120 may be formed. The first-second contact hole H2-1 may be formed to overlap the first-second connection area CNA2-1 in a plan view. A data line contact hole H-DL penetrating through the first insulating layer 110 and the second insulating layer 120 may be formed, and the data line contact hole H-DL may overlap the first data line DL1 in a plan view.

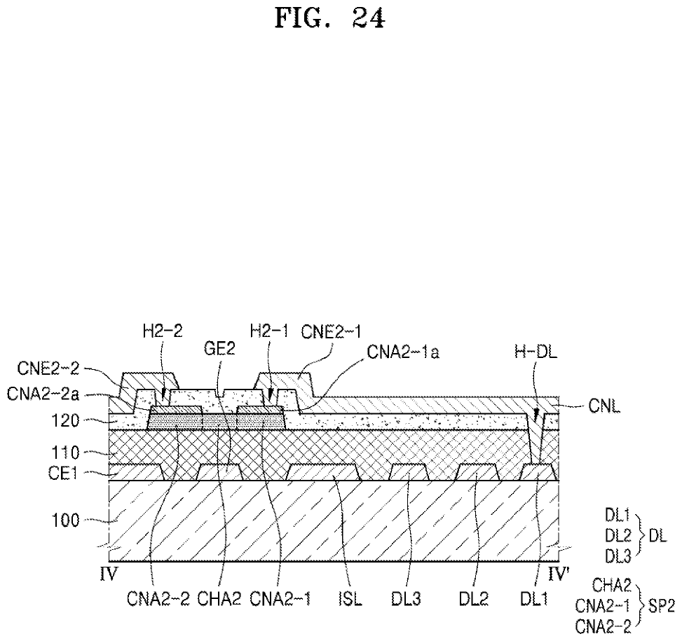

Then, as shown in FIG. 24, the first-second connection electrode CNE2-1 and the connection line CNL may be formed on the second insulating layer 120. In detail, the first-second connection electrode CNE2-1 and the connection line CNL may be integrally formed with each other through the same process.

According to one or more embodiments as described above, a display apparatus capable of stably applying an electrical signal to a gate electrode may be realized. Of course, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a substrate;
an oxide semiconductor layer above the substrate, and comprising a first channel area, and a second channel area spaced from the first channel area;
a first conductive layer between the substrate and the oxide semiconductor layer, and comprising a first gate electrode overlapping the first channel area; and
a second conductive layer above the oxide semiconductor layer, and comprising a shielding layer overlapping the first channel area, and a second gate electrode overlapping the second channel area.

2. The display apparatus of claim 1, wherein the shielding layer and the second gate electrode comprise a same material and have a same layer structure.

3. The display apparatus of claim 1, further comprising:
a first insulating layer covering the first conductive layer, and between the first conductive layer and the oxide semiconductor layer; and
a second insulating layer covering the oxide semiconductor layer, and between the oxide semiconductor layer and the second conductive layer,
wherein the oxide semiconductor layer further comprises:
a first connection area contacting the first channel area, and at least partially having different electrical properties from electrical properties of the first channel area; and
a second connection area contacting the second channel area, and at least partially having different electrical properties from electrical properties of the second channel area, and
wherein the second conductive layer further comprises:
a first connection electrode electrically connected to the first connection area via a first contact hole defined by the second insulating layer; and
a second connection electrode spaced from the first connection electrode, and electrically connected to the second connection area via a second contact hole defined by the first insulating layer and the second insulating layer.

4. The display apparatus of claim 3, wherein the first insulating layer covers the first conductive layer to correspond to an entire surface of the substrate, and
wherein the second insulating layer is between the first insulating layer and the second conductive layer outside the oxide semiconductor layer.

5. The display apparatus of claim 4, wherein the second insulating layer is below the second conductive layer.

6. The display apparatus of claim 3, wherein the first connection electrode is integrally formed with the shielding layer.

7. The display apparatus of claim 3, wherein the first conductive layer further comprises a scan line extending in a first direction.

8. The display apparatus of claim 7, wherein the second conductive layer further comprises a data line extending in a second direction crossing the first direction.

9. The display apparatus of claim 8, wherein the first conductive layer further comprises a connection line for electrically connecting the data line and the second connection electrode.

10. The display apparatus of claim 1, wherein the first conductive layer comprises a first capacitor electrode,
wherein the oxide semiconductor layer comprises a second capacitor electrode overlapping the first capacitor electrode, and
wherein the second capacitor electrode has different electrical properties from electrical properties of the first channel area.

11. The display apparatus of claim 10, further comprising a display element electrically connected to the second capacitor electrode, and comprising a pixel electrode, an emission layer, and an opposite electrode.

12. The display apparatus of claim 11, wherein the second capacitor electrode is directly in contact with the pixel electrode.

13. A display apparatus comprising:
a substrate;
an oxide semiconductor layer above the substrate, and comprising a first channel area, and a second channel area spaced from the first channel area;
a first conductive layer between the substrate and the oxide semiconductor layer, and comprising a first gate electrode overlapping the first channel area, and a second gate electrode overlapping the second channel area; and
a second conductive layer above the oxide semiconductor layer, and comprising a shielding layer overlapping the first channel area.

14. The display apparatus of claim 13, wherein the first gate electrode and the second gate electrode comprise a same material and have a same layer structure.

15. The display apparatus of claim 13, further comprising:
a first insulating layer covering the first conductive layer, and between the first conductive layer and the oxide semiconductor layer; and
a second insulating layer covering the oxide semiconductor layer, and between the oxide semiconductor layer and the second conductive layer,
wherein the oxide semiconductor layer further comprises a first connection area contacting the first channel area, and a second connection area contacting the second channel area, and
wherein the second conductive layer further comprises:
a first connection electrode electrically connected to the first connection area via a first contact hole defined by the second insulating layer; and
a second connection electrode spaced from the first connection electrode, and electrically connected to the second connection area via a second contact hole defined by the second insulating layer.

16. The display apparatus of claim 15, wherein the first connection electrode is integrally formed with the shielding layer.

17. The display apparatus of claim 15, wherein the second conductive layer further comprises a scan line extending in a first direction.

18. The display apparatus of claim 17, wherein the first conductive layer further comprises a data line extending in a second direction crossing the first direction.

19. The display apparatus of claim 18, wherein the second conductive layer further comprises a connection line integrally formed with the second connection electrode, and electrically connected to the data line.

20. The display apparatus of claim 15, further comprising:
a first connection metal layer above the first connection area, and corresponding to the first connection area; and
a second connection metal layer above the second connection area, and corresponding to the second connection area.

21. The display apparatus of claim 13, wherein the first conductive layer comprises a first capacitor electrode,
wherein the oxide semiconductor layer comprises a second capacitor electrode overlapping the first capacitor electrode, and
wherein the display apparatus further comprises a capacitor metal layer above the second capacitor electrode, and corresponding to the second capacitor electrode.

22. The display apparatus of claim 21, further comprising a display element electrically connected to the second capacitor electrode, and comprising a pixel electrode, an emission layer, and an opposite electrode.

23. The display apparatus of claim 22, wherein the capacitor metal layer is directly in contact with the pixel electrode.
